(19) United States
(12) Patent Application Publication
(10) Pub. No.: US 2011/0203647 A1
(43) Pub. Date: Aug. 25, 2011

(54) Methods to Improve Efficiency of a Solar Cell

(76) Inventor: Santosh Kumar, San Jose, CA (US)

(21) Appl. No.: 12/774,756

(22) Filed: May 6, 2010

Related U.S. Application Data
(60) Provisional application No. 61/175,914, filed on May 6, 2009.

(51) Int. Cl. H01L 31/02; H01L 31/0216; H01L 31/18

(52) U.S. Cl. 136/255; 136/256; 427/74

(57) ABSTRACT

Methods to convert heat into electricity using pyroelectricity piezoelectricity are disclosed. The pyroelectric material requires temporal temperature gradient Dt/dt to convert heat into electricity. The first disclosed method uses stack of materials with varying specific heat to create a temperature wave and standing temperature wave which provides the required dT/dt. The second method utilizes piezoelectric resonance to provide required dT/dt for the pyroelectric.

### TECHNICAL FIELD

The present disclosure relates generally to the fields of energy conversion from heat to electricity.

### BACKGROUND

Creating a sustained temperature variation is necessary for harvesting energy from pyroelectric materials. All known methods of obtaining a sustained temperature variation require use of external power, external water cooling or a combination of these as well as other means. No solid state method is available to create a temporal sustained temperature-variation without the use of any external power, especially in the field of harvesting solar energy. What is needed is a system and method which creates temporal sustained temperature variations in a solar cell to increase efficiency of the solar cell without the use of external power or cooling.

### Overview

Two methods to create temporal temperature difference are disclosed herein. One disclosed system and method is based on the principal that it requires less heat to increase the temperature of a metal with low specific heat value. The second disclosed system and method is based on Phonon and IR standing waves in a piezoelectric-pyroelectric system.

A pyroelectric material converts the heat to electricity. When used to convert solar heat into electricity, this increases the overall solar energy utilization to convert to electricity by increasing the Open Circuit Voltage (V,) and short circuit current (I,) of the solar cell. This results in increasing the effective output power efficiency of the solar cell.

Pyroelectricity can be used to further enhance the efficiency by biasing the p-n junction of the solar cell with an electromotive force (EMF) produced from the pyroelectric material. Obtaining substantial power output from pyroelectric materials requires creating a constant temporal temperature gradient dT/dt in the material. Methods to create this constant temporal temperature gradient dT/dt within a solar cell is disclosed.

In one embodiment of this disclosure, a stack of layers of multiple material with varying specific heat is used. One of the material used in the stack may be a pyroelectric material. A first traveling temperature wave may be generated using this stack. A second temperature wave traveling in the opposite direction and meeting the requirements of interference interferes with the first traveling wave and creates a standing temperature wave. The standing temperature wave has fluctuating temperature at the same locations, providing the required dT/dt for the pyroelectric to produce stable voltage and current.

a pyroelectric material. A first traveling temperature wave may be generated using this stack. A second temperature wave traveling in the opposite direction and meeting the requirements of interference interferes with the first traveling wave and creates a standing temperature wave. The standing temperature wave has fluctuating temperature at the same locations, providing the required dT/dt for the pyroelectric to produce stable voltage and current.

In another embodiment of this disclosure, materials that charge when exposed to heat, such as pyroelectric material are coated with metal such as titanium on both sides to form electrode. On exposure to the heat and near IR solar radiation the metal on one side of the pyroelectric absorbs the radiation and heat. The metal emits radiation which is similar to black body radiation. This radiation gets reflected from the metal on the opposite side of pyroelectric material and forms a standing wave in the cavity formed by the two metals. The standing wave creates oscillating temperature spots inside the pyroelectric material. The oscillating temperature creates stable voltage and current. The pyroelectric material may also be a piezoelectric. When the pyroelectric is also a piezoelectric, the charge created due to pyroelectric causes vibration in the piezoelectric crystal. The vibration causes temperature oscillation inside the pyroelectric-piezoelectric material which gives rise to electric field. The electric field causes the piezoelectric-pyroelectric crystal to vibrate resulting in a resonance effect. The resonance creates non decaying voltage and current.

Example of Pyroelectric-Piezoelectric material are Aluminum Nitride, PST (Lead Scandium Tantalate), PZT (Lead Zirconium Titanate), Lithium Niobate, Lithium Tantalate, etc.

### BRIEF DESCRIPTION OF THE DRAWINGS

The accompanying drawings, which are incorporated into and constitute a part of this specification, illustrate one or more examples of embodiments and, together with the description of example embodiments, serve to explain the principles and implementations of the embodiments.

In the drawings:

FIG. 1 illustrates a solar cell with a pyroelectric element in accordance with an embodiment.

FIG. 2 a perspective view of the solar cell shown in FIG. 1 in accordance with an embodiment.

FIG. 3A illustrates an example graph of the RMF produced from a pyroelectric element in accordance with an embodiment.

FIG. 3B illustrates a graph of the increase in efficiency from a pyroelectric element.

FIG. 4 illustrates a schematic of a circuit used to the solar cell with pyroelectric element in accordance with an embodiment.

FIG. 5 depicts a representative cross section of a solar cell utilizing pyroelectric material in accordance with an embodiment.

FIG. 6 represents a block diagram of an overall system which is configured to create a temporal thermal gradient in accordance with an embodiment.

FIG. 7 depicts a schematic of a solar cell with an integrated pyroelectric stack in \ accordance with an embodiment.

FIG. 9A depicts a schematic of a solar cell with a plurality of integrated pyroelectric stacks in accordance with an embodiment. FIG. 9B is a detailed view of the solar cell of FIG. 9A.

### DESCRIPTION OF EXAMPLE EMBODIMENTS

Example embodiments are described herein in the context of heat conversion system and method of use. Those of ordinary skill in the art will realize that the following description is illustrative only and is not intended to be in any way limiting. Other embodiments will readily suggest themselves to such skilled persons having the benefit of this disclosure. Reference will now be made in detail to implementations of the example embodiments as illustrated in the accompanying drawings. The same reference indicators will be used throughout the drawings and the following description to refer to the same or like items.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

Those of ordinary skill in the art will recognize that devices of a less general purpose nature, such as hardwired devices, field programmable gate arrays (FPGAs), application specific integrated circuits (ASICs), or the like, may also be used without departing from the scope and spirit of the inventive concepts disclosed herein. It is understood that the phrase “an embodiment” encompasses more than one embodiment and is thus not limited to only one embodiment. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Eraseable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card, paper tape and the like) and other types of program memory.

As used herein, the symbol n+ indicates an n-doped semiconductor material typically having adopting level of n-type dopants on the order of 10²⁰ atoms per cubic centimeter or more. The designation n- or N-type indicates an n-doped semiconductor material (such a silicon (Si), germanium (Ge), Gallium Arsenide (GaAs), and the like) typically having a doping level on the order of 10¹⁷ atoms per cubic centimeter for n doped wells and on the order of 10¹⁵ atoms per cubic centimeter for n substrate material. The designation pt or P-Type indicates a p-doped semiconductor material typically having a doping level of p type dopants on the order of 10²⁰ atoms per cubic centimeter or more. The symbol p indicates a p-doped semiconductor material typically having a doping level on the order of 10¹⁷ atoms per cubic centimeter for p doped wells and on the order of 10¹⁵ atoms per cubic centimeter for p substrate material. Those of ordinary skill in the art will now realize that a range of doping concentrations around those described above will also work. Furthermore, the devices described herein may be formed on a conventional semiconductor substrate or they may as easily be formed as a thin film transistor (TFT) above the substrate, or in silicon on an insulator (SOI) such as glass (SOG), sapphire (SOS), or other substrates as known to those of ordinary skill in the art. Essentially, any process capable of forming pFETs and nFETs will work. Doped regions may be diffusions or they may be implanted. When it is said that something is doped at approximately the same level as something else, the doping levels are within a factor of ten of each other, e.g., 10¹⁶ is within a factor of ten of 10¹⁵ and 10¹⁷.

In general, the system and method described herein enables the use of one or more pyroelectric materials in use with a heat source such as solar cell to create electrical power. Such electrical power may be used in conjunction with a solar cell to increase the electrical output efficiency of the solar cell. More than 70% of photons incident on a solar cell produce heat which are not typically utilized by the solar cell to produce electricity. The system and method employs the use of one or more pyroelectric materials desirably along with power generation devices and/or thermally conductive materials to convert heat such has the heat generated from the photons not utilized by the solar cell into electricity.

In an embodiment, one or more layers of pyroelectric material are deposited onto a substrate. The substrate may be a solar cell during the manufacturing of the solar cell in which the solar cell integrates the pyroelectric material therein. In an embodiment, the solar cell is able to be modified by applying the pyroelectric material thereto.

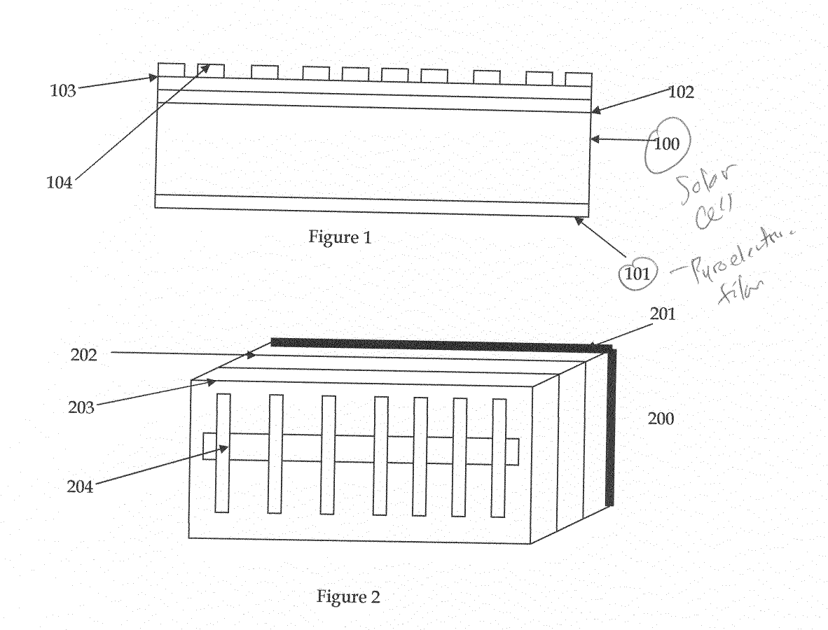

FIG. 1 illustrates a side view of a solar cell with a pyroelectric element in accordance with an embodiment. FIG. 2 illustrates a perspective view of the solar cell the pyroelectric element in accordance with an embodiment. As shown in FIGS. 1 and 2, the solar cell 100 includes a body 102 with a top surface 104 and a bottom surface 106. As shown in FIGS. 1 and 2, a layer of P-type silicon 108 is disposed on the top surface 104. Additionally, a layer of N-type silicon 110 is disposed on top of the P-type silicon 108, whereby a p-n junction 116 is present at the region between the P-type layer 108 and the N-type layer 110. As shown in FIGS. 1 and 2, a collector gnd 110 is disposed on top of the N-type layer 1 10. An encapsulate 114 is desirably disposed on top of the collector grid 110 to protect the solar cell 100.

As shown in FIGS. 1 and 2, the present solar cell 100 includes one or more layers of a pyroelectric element 101 disposed on the bottom surface of the cell body 102. It should be noted that the pyroelectric element 101 may additionally or alternatively be disposed on the top surface of the cell body 102. It is also contemplated that the pyroelectric element 101 may additionally or alternatively be disposed within or between layers of other components in the solar cell body 102.

The pyroelectric element can made of an optically transparent or opaque material. Examples of transparent Pyroelectric materials include, but are not limited to, Poly Vinylidene Fluoride (PVDF) film or Tri Glycerin Sulphate (TGS). Examples of opaque Pyroelectric materials include, but are not limited to, PZT (Lead Zirconate Titanate), PST (Lead Stannic Titanate) and LiTa03 (Lithium Tantalate). It should be noted that other Pyroelectric materials not listed above are contemplated and are thus not limited to those above.

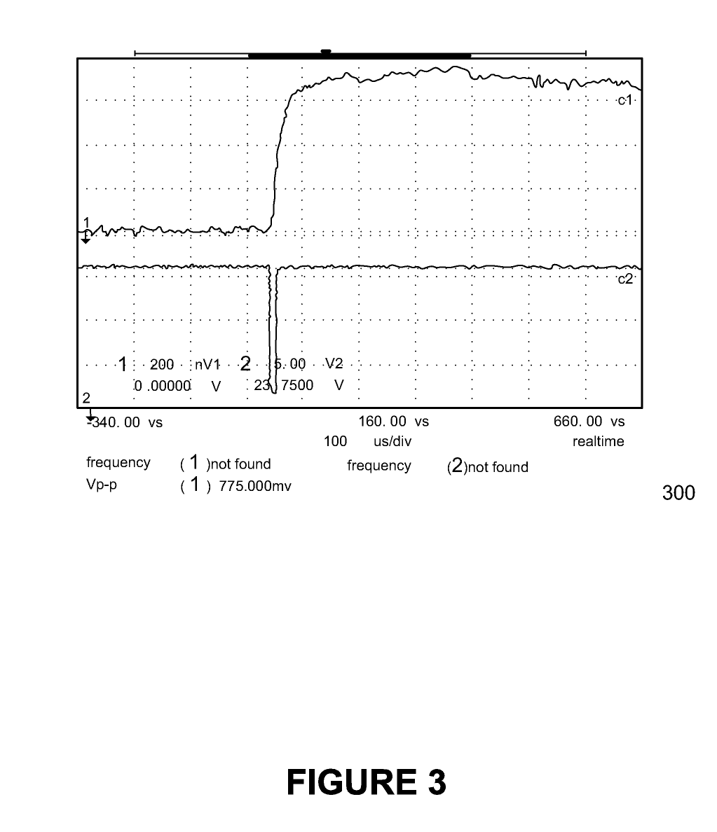

Upon sunlight and ultraviolet rays striking the solar cell 100, heat is generated and collected by the solar cell 100, whereby the heat travels from the cell body toward to the pyroelectric element 10 1. The heat causes the pyroelectric element 10 1 to produce an electric field between the element 101 in the form of an electromotive force (EMF). However, for the pyroelectric element to produce the electrical power, a temporal thermal gradient dT/dt must exist between the top and bottom surfaces of the pyroelectric element. As shown in the graph 300 in FIG. 3, approximately 500 mV of electromotive force (EMF) is produced when heat of approximately 50 mV1 mJ with 930 W of solar energy per square meter is applied to the pyroelectric element.

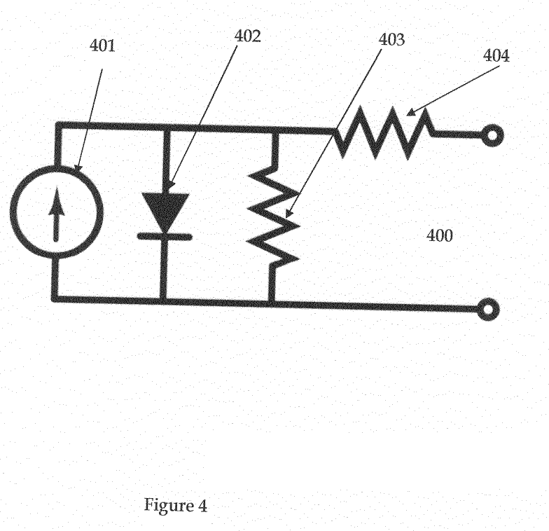

This EMF produced from the pyroelectric element is used by the device 100 to further bias the p-n junction 116 in the solar cell 100. FIG. 4 illustrates a schematic circuit diagram of the system in accordance with an embodiment. The circuit 400 in FIG. 4 includes the solar cell 402 in parallel to one or more pyroelectric elements 406 as well as one or more power generation devices 404, such as a semiconductor diode, which is also desirably in parallel with the cell 402 and pyroelectric element 406. Additionally, one or more resistors 408 are in parallel with the other elements in the circuit. Further, one or more resistors 410 are in series with the solar cell 402.

Regarding the power generation device 404, the device 404 is preferably a semiconductor diode, including but not limited to a Schottky diode, Zener diode, PIN diode, and the like. It should be noted that although only one semiconductor diode is shown in the figure and described herein, more than one semiconductor diode is contemplated. Additionally or alternatively, although only one pyroelectric element 406 is shown in the figure and described herein, more than one pyroelectric element 406 is contemplated.

The pyroelectric element 406 can be considered a current/voltage source, because it produces electrical power when a temporal thermal gradient dT1dt is present in the element 406. This EMF produced by the pyroelectric element 406 increases the open circuit voltage V, of the solar cell 402. This increase in the open circuit voltage V, translates into increased power output since power output is defined by the product of the open circuit voltage V, and the short circuit current I. In one implementation, an electron-hole pair (EHP) can be generated at the pn junction in the solar cell due to the pyroelectric element ionizing electrodes at the pn junction and depleting the pn region of electrons in the solar cell 402. The EHP thereby allows the electrons to move longer distances along the pn junction, thereby increasing the Short circuit current Isc in the solar cell and increasing the efficiency and overall power output of the solar cell 402.

In an embodiment, the EMF generated from the pyroelectric element 101 is added to the open circuit voltage Voc of the solar cell 100. For example, a solar cell with Voc=500 mV without the pyroelectric element will have the effective Voc of 1000 mV. In addition, the power generation device 200 generates a current I which thereby increases the short circuit current Isc of the solar cell 100. This causes an increase in its power output. As stated, it is well known that the power output of the solar cell is determined by the product of its Open Circuit Voltage V, and the short circuit current Isc. Therefore if the Open Circuit Voltage V, is doubled, the efficiency of the solar cell 100 is also doubled, assuming no change is made to the short circuit current Isc.

Referring to FIG. 4, upon the pyroelectric element 406 being heated, it generates an EMF which results in up to 5 Amperes of current to be generated by power generation device 404. This current combines with the current from the solar cell 402, thereby resulting in an increase in the power generated by solar cell 402.

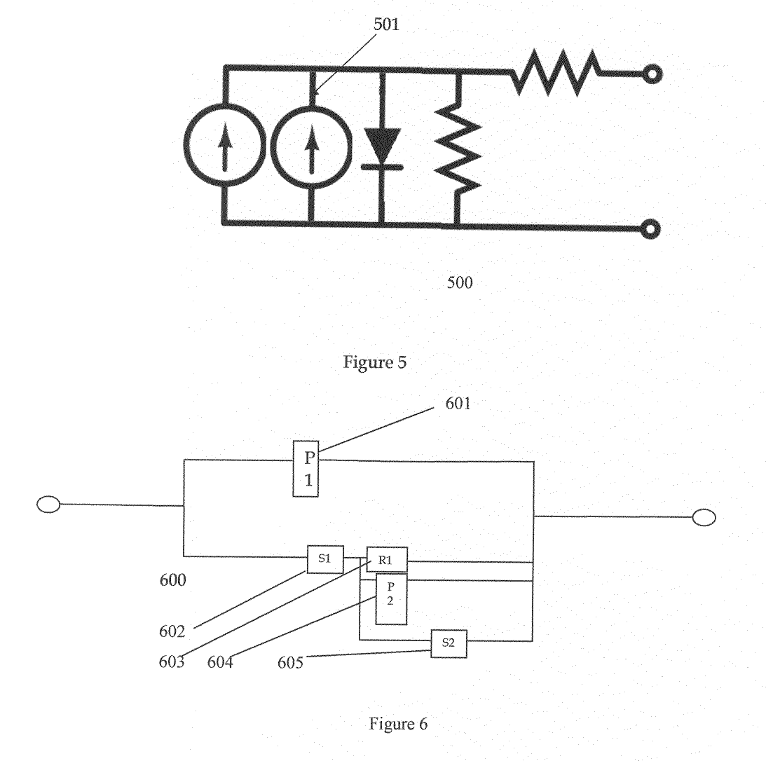

FIG. 5 illustrates a cross sectional view of a solar cell with an integrated pyroelectric element and power generation device in accordance with an embodiment. As shown in FIG. 5, the solar cell 500 includes a N-type layer 502 disposed on top of a P-Type layer 504. An array of electrical contacts 506 are disposed on top of the N-type layer 502, whereby the power generation devices 508 are disposed on the electrical contacts 506. As stated above, the power generation devices 508 are desirably Schottky diodes, although other appropriate types of components are contemplated. The power generation devices 508 are desirably formed in the solar cell 500 by depositing platinum or other appropriate metal on the solar cell 500. Ohmic contacts 703 are created on the rest of the surface of the solar cell where Schottky is created.

As shown in the embodiment in FIG. 5, a non-transparent pyroelectric element 5 10 is desirably disposed on a bottom surface of the P-type layer 504. The pyroelectric element 5 10 is desirably made of Lead Zirconate Titanate (PZT), although other materials are contemplated. The pyroelectric element 510 is deposited below the P-type layer 504 using deposition techniques such as sputtering, screen printing and the like. One or more resistors 512 is desirably deposited below the pyroelectric element 5 10, such that when current passes through the resistor 512, the resistor 512 will produce heat, continuously or intermittently, which then passes to the pyroelectric element 5 10. This change in the temperature over time causes the pyroelectric element 5 10 to produce an EMF. Also, as described above, additional heat is passed to the pyroelectric element 510 which is collected from the sun or accumulated as wasted heat from other components. As explained above, the EMF produced from the pyroelectric element 510 will cause current flow in the power generation device 508, thereby resulting in an increase in the total amount of current produced from the solar cell 500.

As discussed above, a temporal temperature gradient dT/dt is required in the pyroelectric element for the pyroelectric element to produce useable electrical power. In the above embodiment, the heat produced from the resistor 512 which travels to the pyroelectric element may be intermittently or cyclically increased and decreased due to the amount of current passing through the resistor 512. This intermittent or cyclic increase and decrease from the resistor 512 will produce a temporal temperature gradient dT/dt in the pyroelectric element 510. Additionally, current passing through the power generation device 508 would intermittently or cyclically heat a resistor coupled to the device 508, thereby creating the temporal temperature gradient dT/dt in the pyroelectric element 510. As a result, the pyroelectric element 510 will produce EMF which translates into increased power output from the solar cell.

FIG. 6 represents a block diagram of an overall system which is configured to create a temporal thermal gradient in accordance with an embodiment. The circuit 600 shown in FIG. 6 is connected to a solar cell 602, whereby the circuit 600 includes a first pyroelectric element 604, a second pyroelectric element 606, a first power generation device 608, a second power generation device 6 10 and one or more resistors 612. It should be noted that although two pyroelectric elements and power generation devices are shown and described in relation to the circuit in FIG. 6, any number of pyroelectric elements and power generation devices are contemplated.

In the circuit shown in FIG. 6, the first pyroelectric element 604 and the first power generation device 608 are in a parallel configuration with one another with respect to the solar cell 602. Additionally, the first power generation device 608 is serially connected to the resistor 612, whereby the resistor 612, the second pyroelectric element 606, and the second power generation device 608 are configured in parallel with respect to one another.

In operation, the solar cell 602 becomes heated due to the sun's rays, whereby heat produced and collected by the solar cell 602 travels preferably downward toward the first pyroelectric element 604. In response, the first pyroelectric element 604 undergoes a change in temperature over time which causes it to create electricity and pass current into the circuit. In particular, the current passes to the first power generation device 608. Upon the first power generation device 608 receiving the current, the device 608 passes current through the resistor 612 which eventually heats up.

In particular, this current through the first power generation device 608 increases the Isc of the solar cell for a short period of time (e.g. from less than a second to several seconds). The heat is generated by the resistor 612 for a short period of time whereby this heat passes to the second pyroelectric element 606 and creates a change in temperature over time dT/dt. As a result of the temperature change in the second pyroelectric element 606, element 606 produces EMF.

As with the first pyroelectric element 604, the change in voltage V, by the second pyroelectric element 606 causes current to flow. The second power generation device 610. As a result, the second power generation device 610 increases the Isc of the solar cell 602 for the period when the current through the first power generation device 604 decreases. This allows a stable amount of current to flow through the system at all times. In addition, when the current is provided by the second power generation device 6 10, the current travels through the second resistor 616 and thereby heats up the second resistor 616. As a result, the heat produced from the second resistor 616 passes to the first pyroelectric element 604 to apply a temporal thermal gradient to the pyroelectric element 604. A continuous short circuit current Isc of the solar cell 601 is achieved in this manner since the first and second power generation devices 608,610 alternatively apply current to the respective resistors 612,616 to create a constantly changing temperature over time in the pyroelectric elements 604,606.

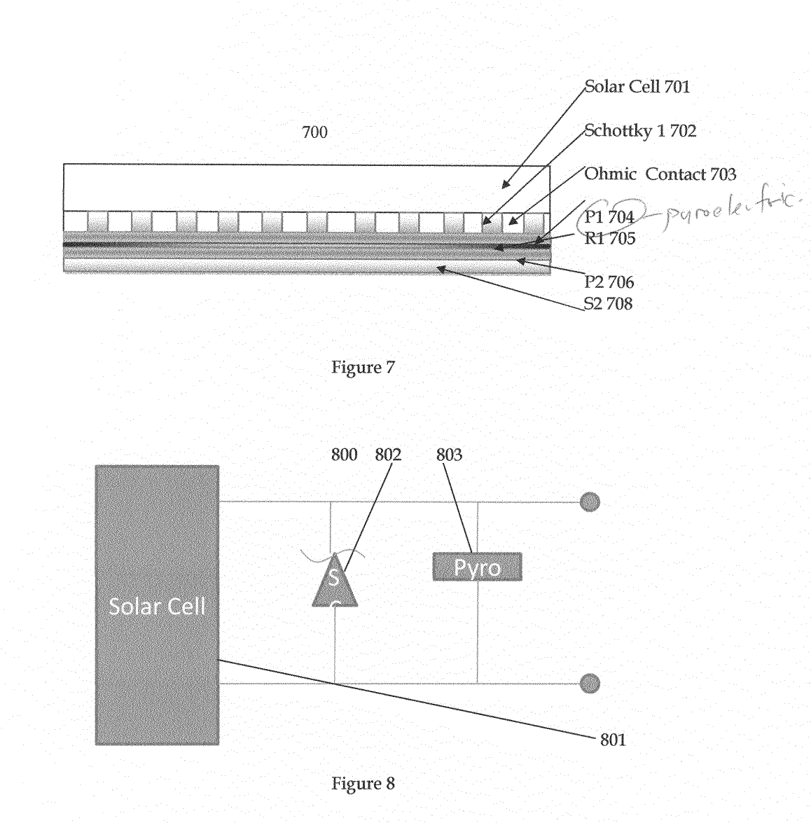

FIG. 7 represents a schematic of the system which creates a temporal thermal gradient in accordance with another embodiment. As shown in FIG. 7, the solar cell 700 includes a N-type layer 702 disposed on top of a P-Type layer 704. An array of electrical contacts 706 are disposed on top of the N-type layer 702, whereby the power generation devices 708 are disposed on the electrical contacts 706. As stated above, the power generation devices 708 are desirably Schottky diodes, although other appropriate types of components are contemplated. In addition, the solar cell 700 includes a plurality of individual pyroelectric elements 710 and 712 which are desirably adjacent to one another. It is desired that at least a pair of pyroelectric elements of the plurality are co-planar and in contact with the solar cell 700. For description purposes, the pyroelectric elements are referred to as the first pyroelectric element 710 and the second pyroelectric element 712. It is preferred that the first pyroelectric element 710 produces EMF from the heat received and collected by the solar cell 700.

In addition, the solar cell 700 includes at least one thermally conductive element 714 which is coupled to the power generation device 708 and the second pyroelectric element 712 In particular, the thermally conductive element 714 is desirably a metal with a low specific heat value, such as copper, tungsten and the like. In an embodiment the thermally conductive element 714 is configured to be in contact with the top surface of the pyroelectric element 712, shown via extension 716. Additionally or alternatively, the thermally conductive element 714 may be in contact with the bottom surface of the pyroelectric element via extension 71 8. Since the thermally conductive element 714 has a low specific heat value, the element 714 will require relatively less externally applied heat to cause it to heat up to a desired temperature. In other words, the element 714 will increase in temperature at a rapid pace when relatively little heat applied to it from the solar cell. This enhances the thermal gradient over a short amount, and the increased temperature of the thermal element 714 will conduct to the pyroelectric element 712, thereby passing to element 712 and increasing the temporal temperature gradient dT/dt in the pyroelectric element 712. A thermal feedback path 907 is used from the output end of schottky to the second pyroelectric 908.

FIG. 8 illustrates a cross sectional view of a solar cell having a pyroelectric assembly in accordance with another embodiment. As shown in FIG. 8; the solar cell 802 includes a first pyroelectric element 804 having a top surface 804A and a bottom surface 804B in which the top surface 804A of the pyroelectric element 804 is desirably disposed on a bottom surface 803 of the cell body 802. Additionally, a first metal layer 806 is disposed on the pyroelectric element 804 and has a top surface 806A and a bottom surface 806B, whereby the top surface 806A of the first metal layer 806 is desirably disposed on the bottom surface 806B of the pyroelectric element 804. Moreover, a second pyroelectric element 808 is disposed on the first metal layer 806, whereby the second pyroelectric element 808 has a top surface 808A and a bottom surface 808B in which the top surface 809A of the second pyroelectric element 808 is desirably in contact with the bottom surface 806B of the second pyroelectric element 808. Although only two sets of pyroelectric elements and metal layers are shown, any number of stacked pyroelectric elements and metal layers are contemplated (e.g. 25 stacked layers).

The metal layers are desirably made of tungsten or any other appropriate materials. It is preferred that the thickness T of at least one of the pyroelectric elements desirably be approximately 1000 Angstroms, although other thickness dimensions are contemplated.

As with the thermal element in FIG. 7, the metal layers 806,810 and so on are desirably made of a material that has a low specific heat value. Therefore, metal layer 806 will heat up relatively quickly from a small amount of heat that travels to it from the first pyroelectric element 804. In other words, the metal layer 806 will have a relatively large dT/dt value. As the first metal layer 806 rapidly increases in temperature, that heat will quickly travel from the first metal layer 806 to the second pyroelectric element 808. As the second pyroelectric element 808 experiences this significant change in temperature over time (i.e. dT/dt), the second pyroelectric element 808 will produce electric power through EMF. This process will repeat downward along the alternating stacks of pyroelectric elements and metal layers to produce an overall increase in electrical power from the pyroelectric elements.

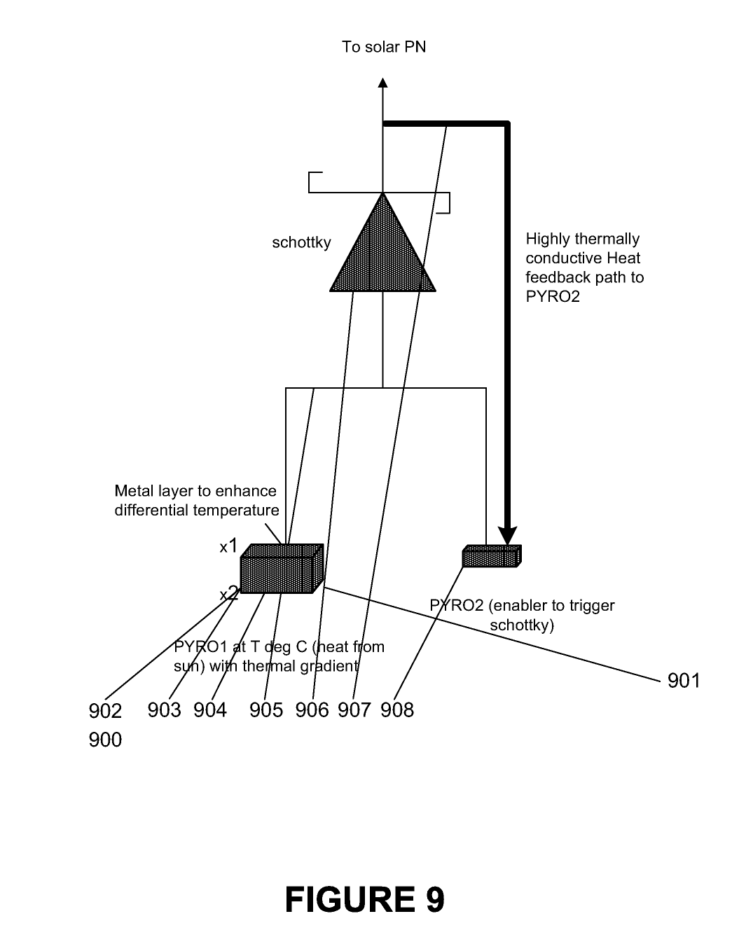

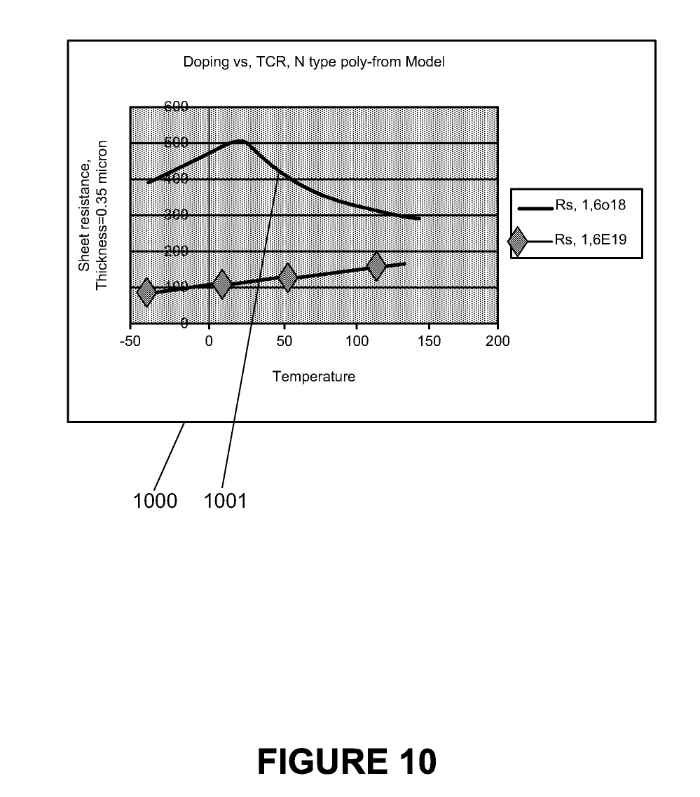

FIG. 9 illustrates a solar cell assembly including multiple pyroelectric assemblies in accordance with an embodiment. As shown in FIG. 9, the assembly 900 includes a solar cell 902 which desirably includes two or more stacks of pyroelectric element assemblies. In particular, the assembly 900 includes a first pyroelectric assembly 902 and a second pyroelectric assembly 904, both of which are disposed on the bottom surface of the solar cell 902. The first pyroelectric assembly 902 desirably includes a first metal layer 906 having a top surface 906A and a bottom surface 906B in which the top surface 906A of the first metal layer 906 is desirably disposed on a bottom surface 903 of the solar cell body 902. Additionally, a first pyroelectric element 908 is disposed on the first metal layer 906 and has a top surface 908A and a bottom surface 908B, whereby the top surface 908A of the first pyroelectric element 908 is desirably disposed on the bottom surface 906B of the first metal layer 906. As described above, the layers of pyroelectric elements and metal layers are stacked in an alternating configuration to maximize the temporal thermal gradient dT/dt in each of the pyroelectric elements in the stack.

In addition, the second pyroelectric assembly 904 includes a stack of alternating pyroelectric elements and metal layers, whereby the configuration of the stack is inverted with respect to the first pyroelectric assembly 902. Thus, the second pyroelectric assembly 904 has a first pyroelectric element 914 disposed on the bottom surface 903 of the solar cell body 902, and the last vertically located component is a metal layer 920.

As shown in FIG. 9, a thermally conductive intermediate member 922 is coupled to the first pyroelectric assembly 902 and the second pyroelectric assembly 904. In particular, the intermediate conductive member 922 is coupled to the first metal layer 906 in the first pyroelectric assembly 902 and the last metal layer 920 in the second pyroelectric assembly 904. The intermediate conductive member 922 functions to transfer heat from the first metal layer 906 to the last metal layer 920.

As described above, heat received from the solar cell travels downward (as shown by arrow 98) along the stack 902, whereby the temperature gradient will gradually decay as the heat travels between layers in the stack. By transferring the heat coming directly from the solar cell 902 to the second pyroelectric stack 904, the heat will need to travel upward among the various layers in the second stack 904 toward the solar cell 902 (as shown by arrow 99). This creates two oppositely traveling thermal waves which, when combined, forms a standing thermal wave between the two stacks 902,904. Considering that the heat is continuously received from the solar cell into the first stack, the heat will continue to travel to the second stack and thus provide a continuous standing wave. This standing wave will therefore continually provide the individual pyroelectric elements a constantly changing the temporal thermal gradient in each pyroelectric element as long as heat is continually provided by the solar cell. In other words, the standing thermal wave creates a non-decaying temporal temperature gradient in each pyroelectric element in which the temperature gradients are continually remaining at the desired values.

While embodiments and applications have been shown and described, it would be apparent to those skilled in the art having the benefit of this disclosure that many more modifications than mentioned above are possible without departing from the inventive concepts disclosed herein. The invention, therefore, is not to be restricted except in the spirit of the appended claims.

In an embodiment, one or more layers of pyroelectric material are deposited onto the a layer of metal deposited on a substrate, which could be silicon or any other material. A layer of metal is then deposited on top of the pyroelectric layer.

FIG. 11 depicts an implementation of this technique. 1100 is a standard solar cell. 1101 is the incident energy on the structure. 1102 and 1103 are the top and bottom electrodes made of metal, such as Titanium. 1104 is the layer of pyroelectric-piezoelectric material which generates an electric field. 1105 are the positive and negative charges respectively, created at the electrodes.

Incident energy 1101 gets absorbed by the top electrode 1102 and emits black body radiation into the pyroelectric-piezoelectric material 1104. The material 1104 gets charged and causes mechanical oscillations in the material 1104. These oscillations generate phonons. The phonons get reflected by the bottom electrode 1103. The oncoming and reflected phonons interfere and create standing waves. These standing waves create local thermal oscillations inside the pyroelectic-piezoelectric material giving rise to electric current.

What is claimed is:

1. A method to increase the efficiency of a solar cell by using pyroelectric film to generate emf to bias the solar cell in such a way that the Open Circuit Voltage is increased and by increase the short circuit current from the pyroelectric film

2. Method to deposit pyroelectric film on solar cell on the front of the cell for transparent pyroelectric material.

3. Method to use opaque pyroelectric material not on the front of the solar cell to increase Voc, Isc, power of the efficiency of the solar cell

4. Method to use negative TCR to increase solar cell current with temperature.

5. A method to increase short circuit current of solar using impact ionization in the p-o junction depletion region and using generation devices like schottky, Zener, Avalanche or PIN diodes

6. A method to create Dt/dt for effective functioning of pyroelectric has been disclosed

7. A method to continuously obtain increased short circuit current and increased power using 2 pyroelectric and 2 schottky has been disclosed

8. A method to continuously obtain increased short circuit current and increased power using 2 pyroelectric and 1 schottky has been disclosed.
